(19) United States
(12) Patent Application Publication
(10) Pub. No.: US 2024/0180015 A1
(43) Pub. Date: May 30, 2024

(54) METHOD OF MANUFACTURING FLEXIBLE TRANSPARENT ELECTRODES, FLEXIBLE TRANSPARENT ELECTRODES MANUFACTURED BY THE METHOD, AND ELECTROFIELD LIGHT EMITTING DEVICE HAVING THE FLEXIBLE TRANSPARENT ELECTRODE

(71) Applicant: University-Industry Foundation(UIF), Yonsei University, Seoul (KR)

(72) Inventors: Cheolmin PARK, Seoul (KR); Wei JIANG, Seoul (KR); Seokyeong LEE, Seoul (KR)

(73) Assignee: University-Industry Foundation(UIF), Yonsei University, Seoul (KR)

(21) Appl. No.: 18/475,404

(22) Filed: Sep. 27, 2023

(30) Foreign Application Priority Data
Sep. 27, 2022 (KR) 10-2022-0122692

(51) Int. Cl. H10K 71/60; H01B 1/22; H10K 50/81; H10K 50/828

(52) U.S. Cl. CPC H10K 71/60; H01B 1/22; H10K 50/81; H10K 50/828

(57) ABSTRACT

Disclosed is a method for manufacturing a flexible transparent electrode. The method for manufacturing the flexible transparent electrode includes a first step of forming a transparent polymer layer on a substrate; a second step of spray-coating silver nanowires (AgNWs) on the transparent polymer layer; a third step of spray-coating MXene flakes on the transparent polymer layer having the silver nanowires coated thereon; and a fourth step of pressing and, at the same time, heat-treating an upper surface of the transparent polymer layer on which the silver nanowires and the MXene flakes have been coated.

### CROSS-REFERENCE TO RELATED APPLICATION

This application claims a benefit under 35 U.S.C. § 119(a) of Korean Patent Application No. 10-2022-0122692 filed on Sep. 27, 2022, on the Korean Intellectual Property Office, the entire disclosure of which is incorporated herein by reference for all purposes.

### BACKGROUND

### 1. Field

The present disclosure relates to a method for manufacturing a mechanically flexible and optically transparent flexible transparent electrode, the flexible transparent electrode manufactured thereby, and an electroluminescent device including the same.

### 2. Description of Related Art

The development of a high-performance photoelectric device with mechanical flexibility is required. Such a high-performance photovoltaic device is suitable for a wearable and attachable application such as a photoelectric energy harvesting device, a human interaction sensor, and a display.

A flexible and transparent electrode has been extensively studied to develop a high-performance flexible display. For example, the flexible transparent electrode is suitable for a self-emitting device such as quantum dot light-emitting diodes (QLEDs), organic light-emitting diodes (OLEDs), and polymer light-emitting diodes (PLEDs), and these devices may be easily combined with a variety of solution processes for a scalable large-area application.

Compared to a commercially used ITO (Indium Tin Oxide) electrode, a transparent electrode manufactured based on a variety of solution processes capable of treating low-dimensional nanoscale conductors such as carbon nanotubes, reduced graphene oxide, silver nanowire, etc. have problems such as low conductivity and low film quality, due to problems caused by essential structural defects and many physical bonds of nanoconductors to form a network.

Despite inherently high electrical conductivity, excellent mechanical flexibility, and work function tuning ability of MXene (Ti₃C₂), it is not easy to manufacture a flexible transparent electrode with a sufficiently low sheet resistance using MXene (Ti₃C₂), due to numerous grain boundaries, impurities, and structural defects thereof. Furthermore, it has been difficult to develop a high-performance flexible PLED in a conventional direct current (DC) mode due to poor interfacial contact between the MXene electrode and a charge transport layer.

### SUMMARY

One purpose of the present disclosure is to provide a method for manufacturing a transparent flexible electrode that has low sheet resistance, maintains stability against mechanical deformation, and is optically transparent using a solution process.

Another purpose of the present disclosure is to provide a flexible transparent electrode manufactured by the above method.

Still another purpose of the present disclosure is to provide an electroluminescent device having the flexible transparent electrode.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means illustrated in the claims and combinations thereof.

One aspect of the present disclosure provides a method for manufacturing a flexible transparent electrode, the method comprising: a first step of forming a transparent polymer layer on a substrate; a second step of spray-coating silver nanowires (AgNWs) on the transparent polymer layer; a third step of spray-coating MXene flakes on the transparent polymer layer having the silver nanowires coated thereon; and a fourth step of pressing and, at the same time, heat-treating an upper surface of the transparent polymer layer on which the silver nanowires and the MXene flakes have been coated.

In one implementation of the method, the method further comprises, before the first step, treating an upper surface of the substrate with ozone.

In one implementation of the method, the transparent polymer layer is made of PMMA (polymethyl methacrylate).

In one implementation of the method, the transparent polymer layer is formed to have a thickness in a range of 300 to 1000 nm.

In one implementation of the method, in the second step, a solution in which the silver nanowires with an average diameter of 20 to 70 nm and an average length of 10 to 40 μm are dispersed is applied on a surface of the transparent polymer layer in a spray-coating scheme to form a silver nanowire network in which the silver nanowires are joined together.

In one implementation of the method, in the third step, a solution in which MXene flakes with a size of 2 to 5 μm are dispersed is applied on the surface of the transparent polymer layer in a spray-coating scheme, wherein the MXene flakes are attached to interwire junctions of the silver nanowires in the silver nanowire network.

In one implementation of the method, a content of the MXene flakes is in a range of about 0.012 to 0.036 mg based on 1 g of the silver nanowires.

In one implementation of the method, in the fourth step, the transparent polymer layer having the silver nanowires and the MXene flakes coated thereon is heat-treated at 90 to 100° ° C. for 1 to 10 minutes while being physically pressed using a pressure plate.

Another aspect of the present disclosure provides a flexible transparent electrode comprising: a transparent polymer layer; a silver nanowire network disposed on a surface of the transparent polymer layer and having at least a portion buried in the transparent polymer layer; and MXene flakes attached to interwire junctions of the silver nanowires in the silver nanowire network.

In one implementation of the flexible transparent electrode, the silver nanowire network has a mesh structure of the silver nanowires having an average diameter of 20 to 70 nm and an average length of 10 to 40 μm, wherein each of the MXene flakes has a size of 2 to 5 μm.

In one implementation of the flexible transparent electrode, the MXene flakes are not covered with the transparent polymer layer so as to be exposed.

In one implementation of the flexible transparent electrode, the flexible transparent electrode contains the MXene flakes at a content of about 0.012 to 0.036 mg based on 1 g of the silver nanowires.

Still another aspect of the present disclosure provides an electroluminescent device comprising: a first electrode and a second electrode spaced apart from each other; a light-emitting layer disposed between the first electrode and the second electrode; an electron transport layer disposed between the first electrode and the light-emitting layer; and a hole transport layer disposed between the second electrode and the light-emitting layer, wherein the first electrode includes: a transparent polymer layer; a silver nanowire network disposed on a surface of the transparent polymer layer and having at least a portion buried in the transparent polymer layer; and MXene flakes attached to interwire junctions of the silver nanowires in the silver nanowire network.

In one implementation of the electroluminescent device, the silver nanowire network has a mesh structure of the silver nanowires having an average diameter of 20 to 70 nm and an average length of 10 to 40 μm, wherein each of the MXene flakes has a size of 2 to 5 μm.

In one implementation of the electroluminescent device, the first electrode contains the MXene flakes at a content of about 0.012 to 0.036 mg based on 1 g of the silver nanowires.

According to the method for manufacturing the flexible transparent electrode in accordance with the present disclosure, and the flexible transparent electrode manufactured thereby, the MXene flakes with high electrical conductivity and excellent mechanical flexibility are conformally attached to the interwire junctions of the silver nanowires. Thus, not only may the contact resistance resulting from the junctions between the silver nanowires be reduced, but adhesion therebetween may be improved to improve mechanical properties. Further, a work function of the flexible transparent electrode may be adjusted by controlling the content of the MXene flakes.

As a result, the electroluminescent device including the flexible transparent electrode may have improved performances such as luminous efficiency and external quantum efficiency.

Effects of the present disclosure are not limited to the above-mentioned effects, and other effects as not mentioned will be clearly understood by those skilled in the art from following descriptions.

### BRIEF DESCRIPTION OF DRAWINGS

FIG. 1 is a flowchart for illustrating a method for manufacturing a flexible transparent electrode according to an embodiment of the present disclosure.

In FIG. 2, a is a diagram schematically illustrating a MXAg@PMMA electrode, b is a surface SEM image of a MXAg film, c to e represent a cross-sectional SEM image, a cross-sectional TEM image, and an AFM image of the MXAg@PMMA film, respectively, and f is a photograph of a MXAg@PMMA large-area electrode, g is a graph showing a transmittance of each of the MXAg film and the MXAg@PMMA film, h is a graph showing a sheet resistance and a transmittance of the MXAg@PMMA film based on a varying MXene deposition volume, i represents a HR-XPS profile with Ag 3d of each of the MXAg film and the MXAg@PMMA film, and j represents a HR-XRD spectrum of each of MXene, AgNWs, and MXAg films.

In FIG. 3, a is a graph showing ΔR/R₀ based on a bending radius of each of ITO, MXAg, and MXAg@PMMA electrodes formed on a PET substrate, b is a graph showing ΔR/R₀ based on a bending cycle of each of ITO, MXAg, and MXAg@PMMA electrodes formed on a PET substrate, c is a graph showing ΔR/R₀ at a bending radius of 3 nm and 1000 bending cycles of each of ITO, MXAg, and MXAg@PMMA electrodes formed on a PET substrate, and d is SEM images of the MXAg@PMMA electrode formed on the PET substrate before and after 1000 bending cycles.

In FIG. 4, a shows UPS (UV photoelectron spectroscopy) results of a secondary-electron cutoff energy (left) and onset of valence band energy (right) of the MXAg@PMMA electrode manufactured under a varying deposition volume of the MXene dispersion solution, b is a graph showing change in a work function based on the deposition volume of the MXene dispersion solution, c is a graph showing the results of measuring the change in a current density based on a voltage of the MXAg@PMMA electrode manufactured under a varying deposition volume of the MXene dispersion solution, d is a diagram showing the results of measuring EOD and HOD in a range from 0.5V to 1V and device structures of EOD and HOD.

In FIG. 5, a is a diagram showing a structure of a MXAg@PMMA electrode-based flexible inverted QLED device, b is the energy level diagram of the XAg@PMMA electrode-based flexible inverted QLED device, c and d are graphs measuring the current density change and luminance change based on the applied voltage of each of QLEDs equipped with an ITO electrode, a MXAg electrode, and a MXAg@PMMA electrode, respectively, e is the result of measuring the EL spectrum of each of QLEDs equipped with the MXAg electrode and the MXAg@PMMA electrode, respectively, f is the result of measuring the EQE change based on the current density of each of QLEDs equipped with the ITO electrode, the MXAg electrode, and the MXAg@PMMA electrode, respectively, and g and h are the results of measuring the normalized luminance behavior based on the operation lifetime of each of QLEDs equipped with the ITO electrode, the MXAg electrode and the MXAg@PMMA electrode, respectively.

In FIG. 6, a and b are graphs showing the luminance change based on the bending radius and the number of bending cycles of each of the MXAg electrode and MXAg@PMMA electrode-based QLEDs, c is a graph showing the luminance change at a 7.5 mm bending radius and 1000 bending cycles of each of the QLEDs equipped with the ITO electrode, the AgNWs electrode, the MXAg electrode, the AgNWs@PMMA electrode, and the MXAg@PMMA electrode, respectively, and d is a graph showing the device performances (EQE and CE) of each of QLEDs manufactured in a solution process using nanomaterial-based transparent electrodes.

### DETAILED DESCRIPTIONS

Advantages and features of the present disclosure, and a method of achieving the advantages and features will become apparent with reference to embodiments described later in detail together with the accompanying drawings. However, the present disclosure is not limited to the embodiments as disclosed below, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

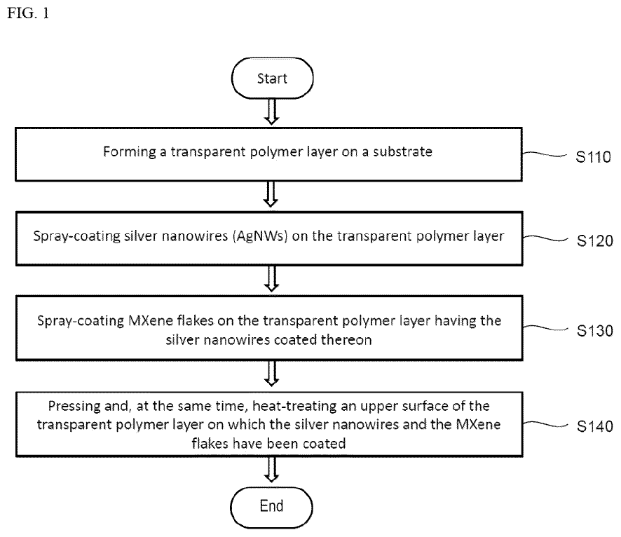

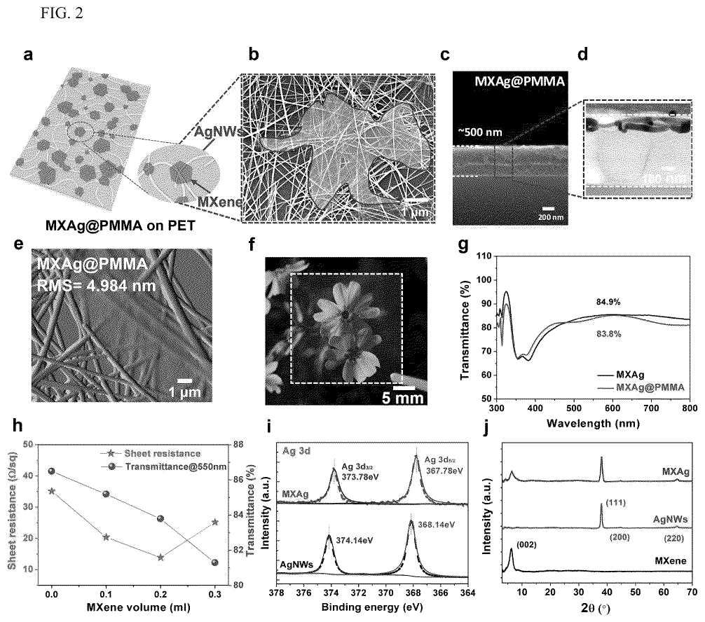

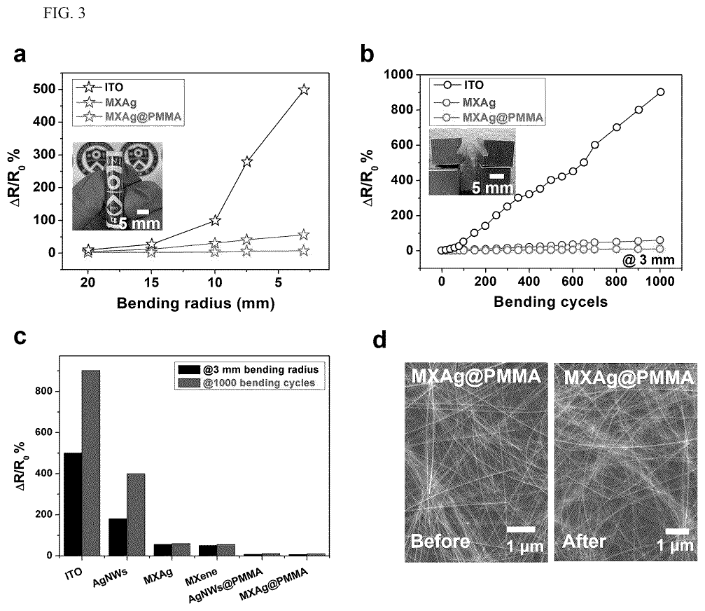

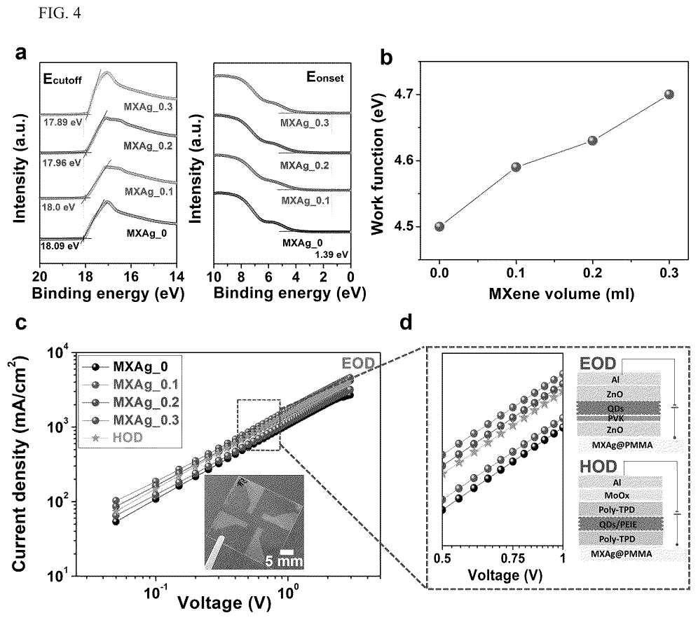

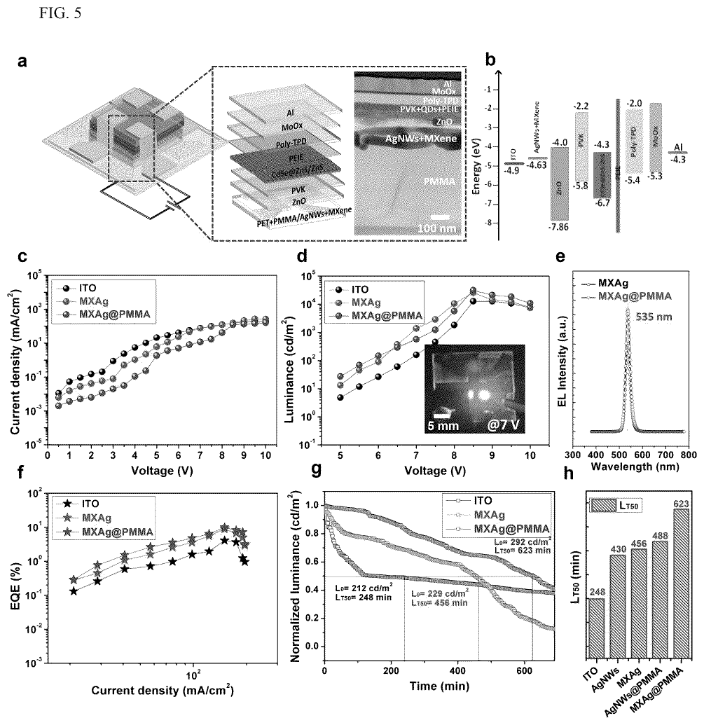

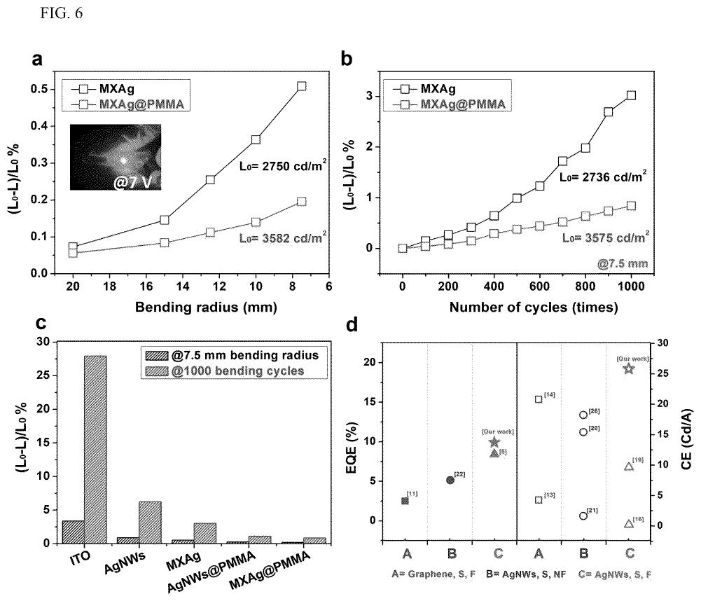

FIG. 1 is a flowchart for illustrating a method for manufacturing a flexible transparent electrode according to an embodiment of the present disclosure.

Referring to FIG. 1, the method for manufacturing the flexible transparent electrode according to an embodiment of the present disclosure may include a first step S110 of forming a transparent polymer layer on a substrate; a second step S120 of spray-coating silver nanowires (AgNWs) on the transparent polymer layer; a third step S130 of spray-coating MXene flakes on the transparent polymer layer having the silver nanowires coated thereon; and a fourth step S140 of pressing and, at the same time, heat-treating an upper surface of the transparent polymer layer on which the silver nanowires and the MXene flakes have been coated.

In the first step S110, a structure or a material of the substrate is not particularly limited as long as the substrate has a flat upper surface, is flexible, and is optically transparent. For example, a substrate made of a polymer such as PET (polyethylene terephthalate) may be used.

In one embodiment, in order to improve adhesion of the substrate with the transparent polymer layer of a finally manufactured flexible transparent electrode, before forming the transparent polymer layer on the substrate, an upper surface of the substrate may be ozone-treated for about 10 to 30 minutes in a pre-treating process.

In one embodiment, the transparent polymer layer may be made of an optically transparent and flexible polymer material. For example, the transparent polymer layer may be made of polymethyl methacrylate (PMMA). The transparent polymer layer may be formed on the substrate in a solution process such as spin-coating. The transparent polymer layer may be formed to have a thickness in a range of about 300 to 1000 nm.

In the second step S120, the silver nanowires (AgNWs) may be applied on the transparent polymer layer surface in a spray-coating scheme. For example, a dispersion solution of silver nanowires having an average diameter of about 20 to 70 nm and an average length of about 10 to 40 μm may be prepared and then applied on the transparent polymer layer surface in a spray-coating scheme. In one example, the dispersion solution of the silver nanowires may contain the silver nanowires at a concentration of about 0.10 to 0.30 wt. %, and the silver nanowire dispersion solution may include water or alcohol as a solvent.

In one embodiment, when the dispersion solution of the silver nanowires is applied on the upper surface of the transparent polymer layer in a spray-coating scheme, a silver nanowire network in which the silver nanowires are joined together may be formed on the upper surface of the transparent polymer layer.

In the third step S130, the MXene flakes may be applied on the surface of the transparent polymer layer on which the silver nanowire network has been formed in a spray-coating scheme. In one embodiment, a dispersion solution in which the MXene flakes having a size of about 2 to 5 μm are dispersed may be prepared and then applied on the surface of the transparent polymer layer on which the silver nanowire network has been formed in a spray-coating scheme. In this regard, the MXene flakes may be attached to interwire junctions of the silver nanowires in the silver nanowire network.

In one embodiment, the MXene flake dispersion solution may contain the MXene flakes at a concentration of about 0.5 to 3.0 mg/mL, and the MXene flake dispersion solution may include water or alcohol as a solvent.

In one embodiment, the MXene flakes may be contained in an amount of about 0.012 to 0.036 mg based on 1 g of the silver nanowires. When the content of the MXene flakes based on 1 g of silver nanowires is smaller than 0.012 g, a problem may occur in which the improvement in electrical conductivity and mechanical stability of the finally manufactured flexible transparent electrode does not reach a target value. When the content thereof exceeds 0.036 g, the electrical conductivity may be lowered.

In the fourth step S140, the transparent polymer layer having the silver nanowires and the MXene flakes coated thereon may be heat-treated under a pressurized condition. For example, the transparent polymer layer having the silver nanowires and the MXene flakes coated thereon may be heat-treated at about 90 to 100ºC for about 1 to 10 minutes while being physically pressed using a pressure plate. When the transparent polymer layer having the silver nanowires and the MXene flakes coated thereon has been heat-treated under the pressure, the MXene flakes may be more conformally attached to the interwire junctions of the silver nanowires in the silver nanowire network. As a result, a surface roughness of the finally manufactured flexible transparent electrode may be reduced. In one example, after the heat-treatment, the flexible transparent electrode may be maintained in a vacuum chamber for a certain period of time to remove air bubbles contained within the flexible transparent electrode.

The flexible transparent electrode according to an embodiment of the present disclosure as manufactured by the above method may include a transparent polymer layer, a silver nanowire network formed on the transparent polymer layer and having at least a portion embedded in the transparent polymer layer, and MXene flakes attached to interwire junctions of the silver nanowires in the silver nanowire network.

In one embodiment, the silver nanowire network may be formed in a mesh of the silver nanowires having an average diameter of about 20 to 70 nm and an average length of about 10 to 40 μm. The silver nanowire network may be located on the transparent polymer layer so that at least a portion thereof is embedded in the transparent polymer layer.

In one embodiment, each of the MXene flakes may have a size of about 2 to 5 μm and may include a single layer or a few layers made of Ti₃C₂Tₓ. The MXene flakes may be conformally attached to the interwire junctions of the silver nanowires in the silver nanowire network and may not be covered with the transparent polymer layer so as to be exposed.

In one embodiment, the flexible transparent electrode may contain the MXene flakes at a content of about 0.012 to 0.036 mg based on 1 g of the silver nanowires.

The MXene flakes have high electrical conductivity and excellent mechanical flexibility. Thus, when the MXene flakes are conformally attached to the interwire junctions of the silver nanowires, a contact resistance resulting from junctions between the silver nanowires may be reduced. Furthermore, when the MXene flakes are attached to the silver nanowire network, a strong capillary interaction between two silver nanowires may be induced while the solvent in a nanogap between the silver nanowires evaporates. Thus, adhesion between the silver nanowires may be improved, and a work function of the flexible transparent electrode may be adjusted.

The flexible transparent electrode according to an embodiment of the present disclosure may be applied as an electrode of an electroluminescent device.

In one embodiment, the electroluminescent device may include a first electrode and a second electrode spaced apart from each other, a light-emitting layer disposed between the first electrode and the second electrode, an electron transport layer disposed between the first electrode and the light-emitting layer and a hole transport layer disposed between the second electrode and the light-emitting layer, wherein the flexible transparent electrode may be applied as the first electrode disposed adjacent to the electron transport layer.

In this case, balance between electrons and holes injected into the light-emitting layer may be adjusted based on the work function adjustment ability of the flexible transparent electrode applied as the first electrode, and as a result, performances such as luminance and outer quantum efficiency of the electroluminescence device may be improved.

In one embodiment, the light-emitting layer may include a quantum dot light-emitting layer, an organic light-emitting layer, a polymer light-emitting layer, etc.

Hereinafter, specific examples of the present disclosure are described in detail. However, the specific examples below are only some embodiments of the present disclosure, and the scope of the present disclosure is not limited to the examples below.

### EXAMPLE 1

A flexible PET substrate was washed with acetone for 15 minutes and then was washed with 2-propanol for 15 minutes and then dried. Afterwards, the washed PET substrate was treated with UV-ozone for 15 minutes.

Subsequently, a PMMA dispersion solution in which PMMA was dispersed at a concentration of 5 wt % in an anisole solvent was spin-coated on the PET substrate under a continuous spin condition (500 rpm, 60 s) and (2000 rpm, 5 s) to form a PMMA buffer layer with a thickness of 500 nm.

Next, 1 ml of an AgNW dispersion solution in which AgNWs with an average length of 25 μm and an average diameter of 50 nm were dispersed at a concentration of 0.15 wt % in a 2-propanol solvent was applied on a surface of the PMMA buffer layer in a spray-coating scheme.

Next, each of various volumes (0.1 ml, 0.2 ml, 0.3 ml) of a MXene dispersion solution in which Ti₃C₂Tₓ (MXene) flakes with a size of 3 μm were dispersed at a concentration of 0.1 mg/ml in a water solvent was applied to the surface of the PMMA buffer layer on which the AgNW dispersion solution has been applied in a spray-coating scheme.

Subsequently, a resulting structure was heat-treated at a temperature of 95ºC for 2 minutes under a pressure of 500 psi. Thus, a MXAg@PMMA electrode was prepared.

Then, the prepared MXAg@PMMA electrode was kept in a vacuum bezel overnight to manufacture a final MXAg@PMMA electrode.

### EXAMPLE 2

A ZnO nanoparticle dispersion solution in which the ZnO nanoparticles were dispersed in ethanol was applied on the MXAg@PMMA electrode manufactured according to Example 1 in a spin-coating scheme (1500 rpm, 30 s), and then was heat-treated for 20 minutes at a temperature of 140° C. in a glove box. Then, the residual solvent was removed therefrom. Thus, a ZnO layer was formed on the MXAg@PMMA electrode.

Next, a PVK solution (10 mg/ml) in which PVK was dissolved in a chlorobenzene solvent was applied on the ZnO layer in a spin-coating scheme (3000 rpm, 30 s) and then heat-treated at a temperature of 140° C. for 10 minutes to form a PVK layer.

Subsequently, a CdSe@ZnS/ZnS quantum dot dispersion solution was applied on the PVK layer in a spin-coating scheme (3000 rpm, 30 s) and then heat-treated at a temperature of 140° ° C. for 10 minutes to form a QD layer.

Subsequently, a PEIE solution (0.5 wt %) was applied on the QD layer in a spin-coating scheme (3000 rpm, 30 s) and then heat-treated at a temperature of 140° C. for 10 minutes to form a PEIE layer.

Next, a poly-TPD solution (10 mg/ml) in which poly-TPD was dissolved in a chlorobenzene solvent was applied thereon in a spin-coating scheme (3000 rpm, 30 s) and then heat-treated at a temperature of 140° C. for 20 minutes to form a poly-TPD layer.

Next, a MoOx solution (10 mg/ml) in which MoOx was dispersed in an acetonitrile solvent was applied thereon in a spin-coating scheme (3000 rpm, 30 s) and then heat-treated at a temperature of 140° C. for 20 minutes to form a MoOx layer.

Subsequently, an Al electrode was formed on the MoOx layer in a thermal deposition scheme. In this way, a QLED device was manufactured.

### EXPERIMENTAL EXAMPLE

In FIG. 2, a is a diagram schematically illustrating a MXAg@PMMA electrode, b is a surface SEM image of a MXAg film, c to e represent a cross-sectional SEM image, a cross-sectional TEM image, and an AFM image of the MXAg@PMMA film, respectively, and f is a photograph of a MXAg@PMMA large-area electrode, g is a graph showing a transmittance of each of the MXAg film and the MXAg@PMMA film, h is a graph showing a sheet resistance and a transmittance of the MXAg@PMMA film based on a varying MXene deposition volume, i represents a HR-XPS profile with Ag 3d of each of the MXAg film and the MXAg@PMMA film, and j represents a HR-XRD spectrum of each of MXene, AgNWs, and MXAg films.

As shown in a in FIG. 2, AgNWs and MXene flakes were formed on a PMMA layer via continuous spray-coating and then thermally treated at 95° C., thereby improving the adhesion of the AgNW network to the PMMA layer, reducing the surface roughness resulting from the AgNW network, and inducing conformal contact of the MXene flakes therewith.

In the MXAg@PMMA electrode, the MXene flakes play following two crucial roles. First, since the MXene flakes which have high electrical conductivity and excellent mechanical flexibility are conformally attached to the interwire junctions of AgNWs at the MXAg@PMMA electrode, the contact resistance resulting from the junctions of the AgNWs may be reduced. Second, the MXene flakes attached onto the AgNW network may induce a strong capillary interaction between two Ag nanowires while the water in the nanogap between the Ag nanowires evaporates, thereby not only improving the adhesion of the AgNWs but also changing the work function of the electrode.

As shown in b in FIG. 2, the MXene flakes with a size of approximately 3 μm were disposed on the AgNWs network. A surface coverage of the MXene flakes on the AgNWs network surface increased as the content of the MXene flakes increased.

As shown in c in FIG. 2, a flat PMMA layer with a thickness of approximately 500 nm is formed on the silicon substrate.

As shown in d in FIG. 2, in the MXAg@PMMA electrode, a portion of the AgNW network hybridized with the MXene flakes was embedded inside the flat PMMA layer. It was identified that in the MXAg film, the MXene flakes were in conformal contact with the interwire junctions of the AgNWs, and the MXene flakes covering the interwire junctions of the AgNWs were in conformal contact with the substrate. These MXene flakes allowed the AgNWs to stably adhere to each other. On the contrary, in absence of the MXene flakes, the interwire junctions of the AgNW network were not bonded to the substrate, and the adhesion between the AgNWs was weak.

As shown in e in FIG. 2, a root-mean-square (RMS) surface roughness of the MXAg@PMMA film as obtained from the AFM image was about 5 nm, while the surface roughness of bare AgNWs and MXag free of the PMMA layer were about 15.47 nm and about 9.87 nm, respectively, thus indicating the important role of the PMMA layer. In one example, even after the ZnO electron transport layer (ETL) of the QLED was formed in the spin-coating manner, the MXAg@PMMA film remained intact. After spin-coating of the ZnO ETL, the surface roughness of the MXAg@PMMA film was reduced from about 5 nm to about 1.46 nm, which indicates that the MXAg@PMMA electrode according to the present disclosure is suitable for the high-performance QLED.

As shown in f and g in FIG. 2, the MXAg@PMMA electrode as prepared by applying 0.2 mL of the MXene dispersion solution on the PET (poly(enthylene terephthalate)) substrate over a large area of 2.5×2.5 cm² was optically transparent in the visible light region, and the transmittance of the MXAg@PMMA film at a wavelength of about 550 nm was about 83.8%. The transmittance of the MXAg@PMMA electrode hardly changed in the visible light region, while the transmittance in the ultraviolet region was reduced due to PMMA which can absorb photon energy in the ultraviolet region. The nanoscale gap between the wire-wire contact of AgNWs and wire-substrate contact resulted in the reduction of the conductivity of a Ag NW electrode. To resolve this issue, a volatile solvent of deionized water was employed to facilitate the welding of the wire junctions, resulting in the improvement of the conductivity. Similarly, we believe that MXene flakes with high conductivity and mechanical flexibility promoted the wire-to-wire welding when they conformally adhered to the wire junctions, resulting in the low sheet resistance of a hybrid electrode with the low surface roughness. The surface roughness of approximately 9.87 nm of the MXAg electrode was lower than that of a networked AgNWs (=15.47 nm), supporting that the MXene flakes promote the wire-to-wire welding.

The haze values of various electrodes were investigated, and all electrodes were found to have similar haze values.

The sheet resistance of the MXAg@PMMA film was approximately 13.9 Ωsq⁻¹, which is sufficiently low and suitable as an electrode for a QLED, as described later.

As shown in h in FIG. 2, based on a result of examining the changes in transmittance and the sheet resistance based on the content of MXene flakes, both transmittance and sheet resistance of the MXAg@PMMA film decreased as the content of the MXene flakes increased. This suggests that the junction resistance between the Ag nanowires is effectively reduced by the conformal contact of the MXene flakes to the interwire junction. The slight decrease in the transmittance as the MXene flakes content increases is due to the presence of multilayered MXene flakes within the MXAg@PMMA film. When 0.3 mL of the MXene flake dispersion solution was applied, the sheet resistance slightly increased to 25.2 Ωsq⁻¹. Considering that the high sheet resistance and low electrical conductivity of the MXene film prepared using the MXene flake dispersion solution at a concentration of 0.4 mg/ml of the MXene flakes are about 450 Ωsq⁻¹ and 1269 Ωcm⁻¹, respectively, excessive MXene flakes which are attached to the junction of the Ag nanowires are believed to increase the sheet resistance of MXAg@PMMA film.

The optimal concentration of the MXene flakes derived based on the results shown in h of FIG. 2 was an deposition volume of 0.2 ml. Based on a result of investigating the transmittance and sheet resistance of various transparent electrodes such as PEDOT:PSS, reduced graphene oxide (rGO), and carbon nanotubes (CNTs), the PEDOT:PSS electrode had a much higher sheet resistance, compared to that of the MXAg@PMMA electrode in accordance with the present disclosure. The hybrid films of rGO and CNT with AgNWs exhibited low sheet resistance values. However, the transmittance thereof was, however, much lower than that of the MXAg@PMMA electrode in accordance with the present disclosure.

As shown in FIGS. 2 i and j, the interaction of MXene flakes with AgNWs in the MXAg@PMMA electrode was examined. The characteristic binding energy peaks representing both MXene and AgNWs were observed in the XPS spectrum of the MXAg@PMMA film. The high-resolution Ag 3d spectra of MXAg@PMMA show that the characteristic binding energies at 374.14 and 368.14 eV are shifted to lower values of 373.78 and 367.78 eV, respectively. The results clearly indicate that additional electron pathways were developed through AgNWs to MXene flakes, causing a change in the work function of the electrode. The peak of TiO₂ in the Ti 2p XPS spectrum of bare MXene was often characterized to examine the oxidation of MXene. It should be noted that in the MXAg@PMMA electrode of the present disclosure where the amount of MXene flakes on the AgNWs was relatively small, compared with a bare MXene film, the TiO₂ peak was rarely observed. Both MXAg and MXAg@PMMA electrodes were rarely varied in their electrical resistances when exposed to air for a time of 70 h or larger. The results in j in FIG. 2 show that the crystalline reflections of both AgNWs and MXenes appear at the same time in the MXAg@PMMA film. The results imply that MXene flakes were physically in contact with the surface of the AgNWs without altering the crystalline structures of the individual AgNWs and MXene flakes.

In FIG. 3, a is a graph showing ΔR/R₀ based on a bending radius of each of ITO, MXAg, and MXAg@PMMA electrodes formed on a PET substrate, b is a graph showing ΔR/R₀ based on a bending cycle of each of ITO, MXAg, and MXAg@PMMA electrodes formed on a PET substrate, c is a graph showing ΔR/R₀ at a bending radius of 3 nm and 1000 bending cycles of each of ITO, MXAg, and MXAg@PMMA electrodes formed on a PET substrate, and d is SEM images of the MXAg@PMMA electrode formed on the PET substrate before and after 1000 bending cycles.

As shown in a in FIG. 3, when the bending radius decreases, a rapid increase in the sheet resistance of the ITO electrode, while the change in the sheet resistance of the MXAg@PMMA electrode was at a negligible level. In particular, the sheet resistance slightly increased as the bending radius decreased even in the bare AgNW@PMMA electrode. This indicates that when the MXene flakes are added, the mechanical and structural integrity is improved due to solid adhesion of the MXene flakes to the interwire junctions between the Ag nanowires, such that the change in the sheet resistance based on the bending radius may be significantly reduced or eliminated. Furthermore, even though the bending radius was reduced, the MXAg@PMMA electrode exhibited a smaller change in the sheet resistance than that in the MXAg electrode without the PMMA layer, thus indicating that the PMMA layer plays an important role in the MXAg@PMMA electrode.

As shown in b and c of FIG. 3, even though the bending cycle increased at a bending radius of 3 nm, the sheet resistance of the MXAg@PMMA electrode hardly changed, while the sheet resistance of the ITO electrode and the AgNW-based electrode changed substantially. The PMMA layer was found to be helpful in increasing the mechanical stability of the MXAg@PMMA electrode, compared with the MXAg electrode.

As shown in d in FIG. 3, the surface morphology of the MXAg@PMMA electrode before and the surface morphology of the MXAg@PMMA electrode after the mechanical deformation were examined using SEM. As a result, almost no mechanical crack-related deformation was observed in the surface morphology even after 1000 bending cycles.

In FIG. 4, a shows UPS (UV photoelectron spectroscopy) results of a secondary-electron cutoff energy (left) and onset of valence band energy (right) of the MXAg@PMMA electrode manufactured under a varying deposition volume of the MXene dispersion solution, b is a graph showing change in a work function based on the deposition volume of the MXene dispersion solution, c is a graph showing the results of measuring the change in a current density based on a voltage of the MXAg@PMMA electrode manufactured under a varying deposition volume of the MXene dispersion solution, d is a diagram showing the results of measuring EOD and HOD in a range from 0.5V to 1V and device structures of EOD and HOD.

As shown in a and b in FIG. 4, the UPS spectrum of each of E_{cutoff} (the secondary-electron cutoff energy) and Eₒₙₛₑₜ (onset of valence band energy) of each of the bare AgNW electrode embedded in the PMMA and three different MXAg@PMMA electrodes with different deposition volumes of 0.1, 0.2, and 0.3 mL of the MXene dispersion solution were obtained. Thus, the work function values (WF) of these electrodes may be calculated using Equation 1 below.

WF=hv−(E_{cutoff}−Eₒₙₛₑₜ) [Equation 1]
where h is Planck's constant and v is the frequency of the incident light. With an hv value of 21.2 eV in the UPS, the WF values of the four different electrodes were 4.5, 4.59, 4.63, and 4.7 eV for bare AgNWs and MXAg@ PMMA with different deposition volumes of 0.1, 0.2, and 0.3 mL of the MXene dispersion solution, respectively. The work function of a bare MXene prepared with 4 mg/mL MXene solution was approximately 4.65 eV. The work function of the hybrid electrode was varied due to physical mixing of the MXene flakes with AgNWs whose work function was approximately 4.5 eV. The work function of a hybrid film prepared with a 0.3 mL volume of MXene solution was approximately 4.7 eV, slightly greater than that of a bare MXene. The large work function obtained in the hybrid film might arise from the change in surface dipoles of the functional groups on the MXene flakes with AgNWs. The work function of MXene flakes was increased upon thermal annealing of a MXene film, which increased the ratio of —O terminated Ti and —F terminated Ti groups on the MXene film. In a hybrid electrode thermally annealed with PMMA, we also observed the increase of the ratio of Ti—O (529.3 eV) and Ti—F (684 eV), which justifies the increase of the work function. The results exhibited that by employing MXene flakes in a AgNW network, there was a decrease in the sheet resistance of the electrode; in addition, there was excellent mechanical stability, and the work function of the electrode was controlled.

As shown in d in FIG. 4, we fabricated an electron-only device (EOD) having a structure of MXAg@PMMA/ZnO/poly(9-vinlycarbazole) (PVK)/QDs/ZnO/Al and a hole-only device (HOD) having a structure of MXAg@PMMA/poly(4-butylphenyldiphenylamine) (poly-TPD)/QDs/polyethylenimine(PEIE)/poly-TPD/phosphomolybdic acid hydrate (MoOx)/Al, and investigated the injection and transport behavior of the electron and hole. Because electron injection occurred from an MXAg@PMMA electrode to the ZnO layer in a QLED, the properties of electron injection through an MXAg@PMMA electrode were systematically examined as a function of the MXene solution deposition volume in the electrode to find an optimal MXAg@PMMA electrode with electron injection current density level comparable to that of the hole current obtained from the HOD. With an increase in the deposition volume of MXene, the current density of the EODs increased owing to the lowered contact resistance in the MXAg@PMMA electrode with MXene flakes, as shown in c in FIG. 4, which is consistent with the results of sheet resistance with MXenes (as shown in h in FIG. 2). An EOD with an MXAg@PMMA electrode having an MXene deposition volume of 0.3 mL exhibited an electron current density lower than that with an MXene deposition volume of 0.2 mL due to the excess MXene flakes in the electrode, which is consistent with the results shown in h in FIG. 2.

The current density behavior of the four EODs and HOD is shown in d in FIG. 4. The results show that the current density of the EOD with MXAg@PMMA having an MXene solution deposition volume of 0.2 mL was well matched with that of the HOD. The comparable hole and electron current densities in the HOD and EOD suggest that one can expect balanced electron and hole injection in a QLED device, resulting in high electroluminescent performance.

In FIG. 5, a is a diagram showing a structure of a MXAg@PMMA electrode-based flexible inverted QLED device, b is the energy level diagram of the XAg@PMMA electrode-based flexible inverted QLED device, c and d are graphs measuring the current density change and luminance change based on the applied voltage of each of QLEDs equipped with an ITO electrode, a MXAg electrode, and a MXAg@PMMA electrode, respectively, e is the result of measuring the EL spectrum of each of QLEDs equipped with the MXAg electrode and the MXAg@PMMA electrode, respectively, f is the result of measuring the EQE change based on the current density of each of QLEDs equipped with the ITO electrode, the MXAg electrode, and the MXAg@PMMA electrode, respectively, and g and h are the results of measuring the normalized luminance behavior based on the operation lifetime of each of QLEDs equipped with the ITO electrode, the MXAg electrode and the MXAg@PMMA electrode, respectively.

A QLED with an inverted architecture was fabricated on a PET substrate through sequential solution deposition of the constituent layers, except for the top Al electrode, as shown schematically in a and b in FIG. 5. An MXAg@PMMA electrode was developed on a PET substrate using spray coating, as described previously, followed by the spin-coating of an ETL of ZnO, PVK, a light-emitting CdSe@ZnS/ZnS quantum dot layer, PEIE, poly-TPD, and MoOx layers. The device was developed by thermally evaporating the top Al electrode on top of the MoOx layer. The light-emitting quantum dot layer was formed using CdSe@ZnS/ZnS quantum dots with a diameter of approximately 13 nm. It was identified that the constituent layers of the manufactured QLED device had energy band alignment.

As shown in c and d of FIG. 5, based on a result of examining the current density-voltage-luminance characteristics of the QLED device equipped with the MXAg@PMMA electrode, the current density of the QLED equipped with the MXAg@PMMA electrode was lower than that of each of the QLED devices equipped with the ITO electrode and the MXAg electrode, respectively, based on the operating voltage. The luminance of the QLED with the MXAg@PMMA electrode was higher than that of each of the QLED devices having the ITO electrode and the MXAg electrode, respectively, based on the operating voltage. The maximum luminance of the QLED with the MXAg@PMMA electrode was about 31340 cd/m² under a voltage of about 8.5 V. The maximum luminance of the QLED devices equipped with the ITO electrode and the MXAg electrode, respectively, were 12702 and 25808 cd/m², respectively under a voltage of about 8.5 V.

As shown in e in FIG. 5, the QLED equipped with the MXAg@PMMA electrode emitted bright green light with a wavelength of approximately 535 nm at the maximum luminance.

As shown in f in FIG. 5, plots of external quantum efficiency (EQE) vs current density were obtained for the three QLEDs, including the QLED with the MXAg@PMMA electrode, and the QLED devices having the ITO electrode and the MXAg electrode, respectively were obtained. An EQE of approximately 9.88% was achieved with the present MXAg@PMMA-QLED, whereas EQEs of approximately 4.08% and 8.79% were obtained for the QLEDs with ITO and MXAg electrodes, respectively. In addition, the high device efficiency was obtained due to the excellent charge recombination balance with an MXAg@ PMMA-based electrode from the current efficiency curve as a function of luminance.

Furthermore, the performance of each of the QLEDs with MXAg@PMMA electrodes prepared with different MXene deposition volumes was examined. The efficiency of a device was improved with increasing the MXene volume to 0.2 mL. The device with a hybrid electrode containing the 0.3 mL MXene volume, however, exhibited an efficiency lower than that of the device with a 0.2 mL MXene volume. The results are consistent with the results of sheet resistance as well as surface roughness of the hybrid electrodes as a function of MXene volume (h in FIG. 2).

The work function of MXAg@PMMA that was tunable with MXene flakes resulted in the MXAg@PMMA-QLED with an EQE 2.4 times higher than that of the QLED with an ITO electrode. The decreased injection barrier resulting from the work function of the MXAg@PMMA electrode was 4.63 eV higher than that of the ITO electrode with 4.9 eV under vacuum-facilitated electron transfer from the anode to the ETL, leading to the recombination balance of electrons and holes in the EML (c and d in FIG. 3). The lower current density of the MXAg@PMMA-QLED compared to that of the ITO based QLED may be due to the decreased leakage current of the MXAg@PMMA-QLED; this could be caused by the injection and recombination balance of electrons and holes.

The MXene flakes with high conductivity and mechanical flexibility promoted the wire-to-wire welding when the MXene flakes conformally adhered to the wire junctions, resulting in the low sheet resistance of a hybrid electrode with the low surface roughness. Moreover, with employing a buffer layer of PMMA, the surface roughness was further reduced, which allowed for developing a uniform charge transport layer on the electrode. Furthermore, the hybrid MXAg@PMMA electrode with its work function slightly greater than that of AgNWs was beneficial for balancing the injection of holes and electrons. Since the mobility of an ETL is greater than that of a hole transport layer (HTL) in the QLED device, the increase in the work function (WF) of the hybrid electrode may reduce the electron mobility, giving rise to the balanced charge injection between holes and electrons.

As shown in g and h in FIG. 5, the MXAg@PMMA-QLED exhibited an operating time of approximately 623 mins at half luminance (L_{T50}) with an initial luminance (L₀) of 292 cd/m², which is much larger than the time required for other QLEDs with ITO, AgNWs, and MXAg electrodes.

In FIG. 6, a and b are graphs showing the luminance change based on the bending radius and the number of bending cycles of each of the MXAg electrode and MXAg@PMMA electrode-based QLEDs, c is a graph showing the luminance change at a 7.5 mm bending radius and 1000 bending cycles of each of the QLEDs equipped with the ITO electrode, the AgNWs electrode, the MXAg electrode, the AgNWs@PMMA electrode, and the MXAg@PMMA electrode, respectively, and d is a graph showing the device performances (EQE and CE) of each of QLEDs manufactured in a solution process using nanomaterial-based transparent electrodes.

Both the MXAg@PMMA-QLED and MXAg-QLED exhibited excellent light-emitting properties with negligible luminance variation based on each of the bending radius and the number of bending cycles, as shown in a and b in FIG. 6. That is, the luminance variation of both devices was smaller than 0.5%. On the other hand, the ITO-QLED exhibited a variation of approximately 3.5% at a bending radius of 7.5 mm, as shown in c in FIG. 6.

The change in luminance of the MXAg@PMMA QLED was again marginal, with a variation of approximately 0.8% after the 1000 bending cycles, as shown in b in FIG. 5. In other words, 99% of the initial luminance of 3575 cd/m² was maintained, even after 1000 bending cycles. The variation in the luminance of approximately 3% was observed for the MXAg-QLED. A large variation in the luminance of approximately 7% was observed for the AgNWs-QLED after the 1000 bending cycles, as shown in c in FIG. 6. Among the QLEDs, the largest luminance change of approximately 28% occurred in the ITO-QLED, which implies an approximately 30% luminance loss of the device with bending cycles (c in FIG. 6).

As shown in d in FIG. 6, the excellent light-emitting properties of the present MXAg@PMMA-QLED with a low sheet resistance and work-function tunable MXAg@PMMA electrode were compared to those of full solution-processed QLEDs with flexible and transparent electrodes based on various nanoconductors such as graphene and AgNWs.

Although the description is made above with reference to preferred embodiments of the present disclosure, those skilled in the art may modify the present disclosure in various ways without departing from the spirit and area of the present disclosure as set forth in the patent claims below, and that it may be changed. A description of the presented embodiments is provided so that a person skilled in the art of any of the present disclosure may use or practice the present disclosure. Various modifications to these embodiments will be apparent to those skilled in the art of the present disclosure. The general principles defined herein may be applied to other embodiments without departing from the scope of the present disclosure. Thus, the present disclosure should not be limited to the embodiments as presented herein, but should be interpreted in the widest scope consistent with the principles and novel features as presented herein.

What is claimed is:

1. A method for manufacturing a flexible transparent electrode, the method comprising:
a first step of forming a transparent polymer layer on a substrate;
a second step of spray-coating silver nanowires (AgNWs) on the transparent polymer layer;
a third step of spray-coating MXene flakes on the transparent polymer layer having the silver nanowires coated thereon; and
a fourth step of pressing and, at the same time, heat-treating an upper surface of the transparent polymer layer on which the silver nanowires and the MXene flakes have been coated.

2. The method of claim 1, wherein the method further comprises, before the first step, treating an upper surface of the substrate with ozone.

3. The method of claim 1, wherein the transparent polymer layer is made of PMMA (polymethyl methacrylate).

4. The method of claim 3, wherein the transparent polymer layer is formed to have a thickness in a range of 300 to 1000 nm.

5. The method of claim 1, wherein in the second step, a solution in which the silver nanowires with an average diameter of 20 to 70 nm and an average length of 10 to 40 μm are dispersed is applied on a surface of the transparent polymer layer in a spray-coating scheme to form a silver nanowire network in which the silver nanowires are joined together.

6. The method of claim 5, wherein in the third step, a solution in which MXene flakes with a size of 2 to 5 μm are dispersed is applied on the surface of the transparent polymer layer in a spray-coating scheme,
wherein the MXene flakes are attached to interwire junctions of the silver nanowires in the silver nanowire network.

7. The method of claim 6, wherein a content of the MXene flakes is in a range of about 0.012 to 0.036 mg based on 1 g of the silver nanowires.

8. The method of claim 6, wherein in the fourth step, the transparent polymer layer having the silver nanowires and the MXene flakes coated thereon is heat-treated at 90 to 100° C. for 1 to 10 minutes while being physically pressed using a pressure plate.

9. A flexible transparent electrode comprising:
a transparent polymer layer;
a silver nanowire network disposed on a surface of the transparent polymer layer and having at least a portion buried in the transparent polymer layer; and
MXene flakes attached to interwire junctions of the silver nanowires in the silver nanowire network.

10. The flexible transparent electrode of claim 9, wherein the silver nanowire network has a mesh structure of the silver nanowires having an average diameter of 20 to 70 nm and an average length of 10 to 40 μm,
wherein each of the MXene flakes has a size of 2 to 5 μm.

11. The flexible transparent electrode of claim 10, wherein the MXene flakes are not covered with the transparent polymer layer so as to be exposed.

12. The flexible transparent electrode of claim 10, wherein the flexible transparent electrode contains the MXene flakes at a content of about 0.012 to 0.036 mg based on 1 g of the silver nanowires.

13. An electroluminescent device comprising:
a first electrode and a second electrode spaced apart from each other;
a light-emitting layer disposed between the first electrode and the second electrode;
an electron transport layer disposed between the first electrode and the light-emitting layer; and
a hole transport layer disposed between the second electrode and the light-emitting layer,
wherein the first electrode includes:
a transparent polymer layer;
a silver nanowire network disposed on a surface of the transparent polymer layer and having at least a portion buried in the transparent polymer layer; and
MXene flakes attached to interwire junctions of the silver nanowires in the silver nanowire network.

14. The electroluminescent device of claim 13, wherein the silver nanowire network has a mesh structure of the silver nanowires having an average diameter of 20 to 70 nm and an average length of 10 to 40 μm,
wherein each of the MXene flakes has a size of 2 to 5 μm.

15. The electroluminescent device of claim 13, wherein the first electrode contains the MXene flakes at a content of about 0.012 to 0.036 mg based on 1 g of the silver nanowires.
